(19) United States
(12) Patent Application Publication
(10) Pub. No.: US 2023/0121581 A1
(43) Pub. Date: Apr. 20, 2023

(54) VARIABLE RESISTANCE MEMORY DEVICE

(71) Applicant: Samsung Electronics Co., Ltd., Suwon-si (KR)

(72) Inventors: Seyun KIM, Seoul (KR); Doyoon KIM, Hwaseong-si (KR); Yumin KIM, Seoul (KR); Hyunjae SONG, Hwaseong-si (KR); Seungyeul YANG, Hwaseong-si (KR)

(73) Assignee: Samsung Electronics Co., Ltd., Suwon-si (KR)

(21) Appl. No.: 17/741,847

(22) Filed: May 11, 2022

(30) Foreign Application Priority Data
Oct. 14, 2021 (KR) 10-2021-0136895

(51) Int. Cl. H01L 27/24

(52) U.S. Cl. CPC H01L 27/2454; H01L 27/249

(57) ABSTRACT

A variable resistance memory device includes: a supporting layer including an insulating material; a variable resistance layer on the supporting layer and including a first layer including a metal oxide and metal nanoparticles, the variable resistance layer including a second layer on the first layer and including an oxide; a channel layer on the variable resistance layer; a gate insulating layer on the channel layer; and a gate electrode on the gate insulating layer. The metal nanoparticles in the variable resistance layer include a first metal capable of combining with oxygen ions of the metal oxide, thereby increasing oxygen vacancies.

### CROSS-REFERENCE TO RELATED APPLICATION

This application is based on and claims priority under 35 U.S.C. § 119 to Korean Patent Application No. 10-2021-0136895, filed on Oct. 14, 2021, in the Korean Intellectual Property Office, the disclosure of which is incorporated by reference herein in its entirety.

### BACKGROUND

Some example embodiments relate to non-volatile memory devices utilizing a variable resistance material.

As a semiconductor memory device, a non-volatile memory device is a memory device in which stored data is not lost, even when power supply is stopped, for example, one or more pf a programmable ROM (PROM), an erasable PROM (EPROM), an electrically EPROM (EEPROM), etc.

Recently, in line with the demand or desire for technology that enables random access to memory cells, next-generation semiconductor memory devices, such as one or more of Magnetic Random Access Memory (MRAM), Phase-Change Random Access Memory (PRAM), and Ferroelectric Random Access Memory (FeRAM) and flash memory devices having the advantages of ROM that maintains stored data even when power is turned off and, at the same time, the advantages of RAM that allows free input and output, have been developed.

The next-generation semiconductor memory device may employ a resistance change element having a characteristic of changing a resistance value according to an applied current or voltage and maintaining a changed resistance value even when the current or voltage supply is stopped. In order to realize high integration and low power, it may be desirable that the resistance change characteristic of the resistance change element occur at a low applied voltage, and therefore, a method for achieving this is continuously being sought.

### SUMMARY

Provided are variable resistance memory devices having improved variable resistance performance.

Additional aspects will be set forth in part in the description which follows and, in part, will be apparent from the description, or may be learned by practice of various example embodiments.

According to some example embodiments, a variable resistance memory device includes: a supporting layer including an insulating material; a variable resistance layer on the supporting layer, which includes a first layer including a metal oxide and metal nanoparticles and a second layer on the first layer and including a second oxide, wherein the metal nanoparticles include a first metal capable of combining with oxygen ions of the metal oxide; a channel layer on the variable resistance layer; a gate insulating layer on the channel layer; and a gate electrode on the gate insulating layer.

The second layer contacts the channel layer, and the second oxide included in the second layer may be or may include an oxide of the channel layer material.

The channel layer may include a poly-Si (polysilicon) material, and the second layer may include a silicon oxide.

An oxide formation energy of the first metal may be lower than the oxide formation energy of silicon (Si).

The oxide formation energy of the first metal may be −880 kJ/mol or lower.

The oxide formation energy of the first metal may be less than or equal to the oxide formation energy of the second metal included in the metal oxide.

The second metal included in the metal oxide may be selected from the group including/consisting of Rb, Ti, Ba, Zr, Ca, Hf, Sr, Sc, B, Mg, Al, K, Y, La, Si, Be, Nb, Ni, Ta, W, V, La, Gd, Cu, Mo, Cr, or Mn.

The first metal included in the metal nanoparticles may be selected from the group including/consisting of Gd, Sc, Y, Ca, Er, Tm, Ho, Lu, Dy, Th, Be, Sm, Yb, Nd, Mg, Ce, La, Sr, Li, Eu, Al, Hf, Zr, Ba, Eu, or Ti.

The metal oxide may be HfO₂, and the metal nanoparticles may be selected from the group including/consisting of Y, Mg, La, Al, Zr, or Ti.

The metal oxide may be HfO₂, and the metal nanoparticles may be selected from the group including/consisting of Y, Mg, or La.

The oxide formation energy of the first metal may be less than the oxide formation energy of the second metal included in the metal oxide, and an absolute value difference between the oxide formation energy of the first metal and the oxide formation energy of the second metal may be 20 kJ/mol or more.

An oxygen vacancy formation energy of the variable resistive layer may be less than 0.5 eV.

In response to the variable resistance layer being in a high resistance state, the number of oxygen vacancies per unit volume may be 2/nm³ or more.

A diameter of the metal nanoparticles may be less than 2.5 nm.

The content of the first metal included in the second layer may be greater than 0 at % and may be less than or equal to 40.0 at %.

An atomic value of the first metal may be 1, and the content of the first metal may be in a range from about 25.0 at % to about 33.3 at %.

The atomic value of the first metal may be 2, and the content of the first metal may be in a range from about 14.3 at % to about 20.0 at %.

The atom of the first metal may be 3, and the content of the first metal may be in a range from about 10.3 at % to about 14.3 at %.

The atomic value of the first metal may be 4, and the content of the first metal may be in a range from about 7.7 at % to about 11.1 at %.

The atom of the first metal may be 5, and the content of the first metal may be in a range from about 6.3 at % to about 9.1 at %.

The gate electrode may include a plurality of gate electrodes that are spaced apart from each other in a first direction parallel to the channel layer, and a plurality of insulators may be respectively between the plurality of gate electrodes.

The supporting layer may have a cylinder shape extending in the first direction, and the variable resistance layer, the channel layer, the gate insulating layer, and the plurality of gate electrodes may have a shape surrounding the insulating layer.

A length in the first direction between the centers of two adjacent gate electrodes among the plurality of gate electrodes may be less than 20 nm.

The variable resistance memory device may further include a drain region in contact with one end of the channel layer and a source region in contact with the other end of the channel layer and the variable resistance layer in the first direction.

The variable resistance memory device may further include a bit line connected to the drain region, a source line connected to the source region, and a plurality of word lines respectively connected to the plurality of gate electrodes.

According to some example embodiments, a memory system includes: a memory device including a memory cell array in which a plurality of memory cells including a variable resistance memory device are arrayed and a voltage generator configured to generate a voltage to be applied to the memory cell array; and a memory controller configured to control the memory device.

According to some example embodiments, a variable resistance device may include a support layer; a variable resistance layer on the support layer, and including a first layer including a metal oxide and metal nanoparticles, wherein the metal nanoparticles include a first metal capable of combining with oxygen ions of the metal oxide; and a channel layer on the variable resistance layer.

The variable resistance layer may further comprise a second layer on the first layer, the second layer including a native oxide of the channel layer.

The second layer may be directly on the first layer.

The channel layer may be directly on the variable resistance layer.

The metal oxide may be HfO₂, and the metal nanoparticles may be one or more from Y, Mg, La, Al, Zr, or Ti.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a structure of a variable resistance memory device according to some example embodiments;

FIG. 2 shows an equivalent circuit for the variable resistance memory device of FIG. 1;

FIG. 3 is a conceptual diagram illustrating an operation of the variable resistance memory device of FIG. 1;

FIG. 4 is a graph illustrating oxygen vacancy formation energies for various materials that may be applied to a variable resistance layer of the variable resistance memory device of FIG. 1;

FIG. 5 is a graph conceptually illustrating an I-V curve according to a density of oxygen vacancies that may be formed in a variable resistance layer of the variable resistance memory device of FIG. 1;

FIG. 6 is a distribution diagram illustrating a density of oxygen vacancies that may be formed in the variable resistance layer according to a valence and content of metal nanoparticles applied to the variable resistance layer of the variable resistance memory device of FIG. 1;

FIG. 7 is a schematic cross-sectional view illustrating a structure of a variable resistance memory device according to some example embodiments;

FIG. 8 is a schematic perspective view illustrating a structure of a memory string included in the variable resistance memory device of FIG. 7;

FIG. 9 is an equivalent circuit diagram of the variable resistance memory device of FIG. 7;

FIG. 10 is a schematic block diagram illustrating a structure of a memory system according to some example embodiments;

FIG. 11 is a block diagram illustrating an example of implementation of a memory device included in the memory system of FIG. 10;

FIG. 12 is a block diagram illustrating a memory cell array included in the memory system of FIG. 10; and

FIG. 13 is a block diagram illustrating a neuromorphic apparatus and an external device connected thereto, according to some example embodiments.

### DETAILED DESCRIPTION

Reference will now be made in detail to various embodiments, examples of which are illustrated in the accompanying drawings, wherein like reference numerals refer to like elements throughout. In this regard, various example embodiments may have different forms and should not be construed as being limited to the descriptions set forth herein. Accordingly, various example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereafter, the inventive concept will be described more fully with reference to the accompanying drawings. Various example embodiments of inventive concepts are capable of various modifications and may be embodied in many different forms. In the drawings, like reference numerals refer to like elements, and the size of each component may be exaggerated for clarity and convenience of explanation.

In the following descriptions, when an element or layer is referred to as being “on” or “above” another element or layer, the element or layer may be directly on another element or layer or intervening elements or layers.

It will be understood that, although the terms “first”, “second”, etc. may be used herein to describe various elements, these terms are only used to distinguish one element from another. These terms do not limit the difference in the material or structure of the components.

In the following descriptions, the singular forms include the plural forms unless the context clearly indicates otherwise. When a part “comprises” or “includes” an element in the specification, unless otherwise defined, it is not excluding other elements but may further include other elements.

Also, in the specification, the term “units” or “ . . . modules” denote units or modules that process at least one function or operation, and may be realized by hardware, software, or a combination of hardware and software.

The term “above” and similar directional terms may be applied to both singular and plural.

Operations of all methods described herein may be performed in any suitable order unless otherwise indicated herein or otherwise clearly contradicted by context. The use of any and all examples, or other language (e.g., “such as”) provided herein, is intended merely to better illuminate inventive concepts and does not pose a limitation on the scope of inventive concepts unless otherwise claimed.

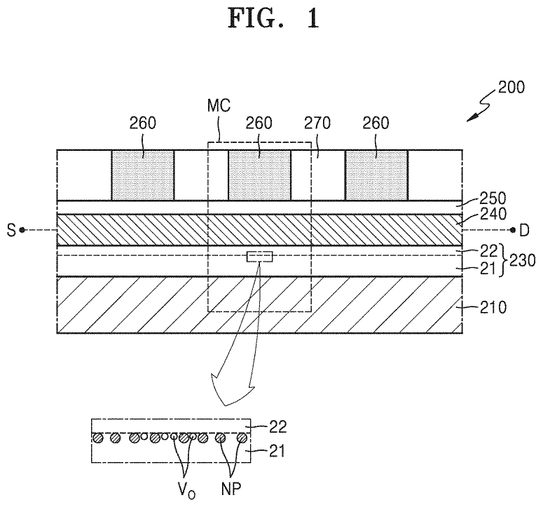

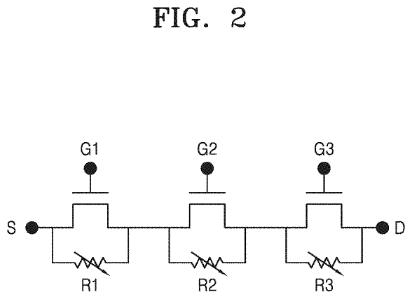

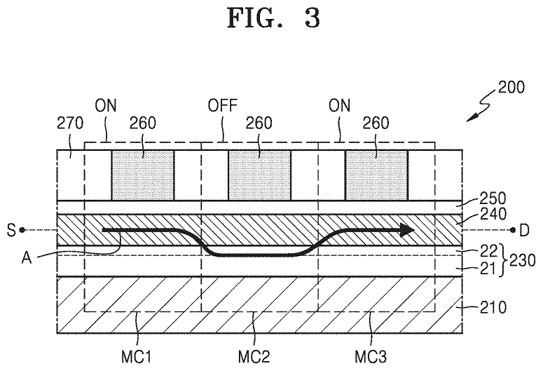

FIG. 1 is a schematic cross-sectional view of a structure of a variable resistance memory device 200 according to some example embodiments, and FIG. 2 shows an equivalent circuit for the variable resistance memory device 200 of FIG. 1. FIG. 3 is a conceptual diagram illustrating an operation of the variable resistance memory device 200 of FIG. 1.

Referring to FIG. 1, the variable resistance memory device 200 includes: a supporting layer 210 including an insulating material; a variable resistance layer 230 on the supporting layer 210 and including a variable resistance material; a channel layer 240 on the variable resistance layer 230; a gate insulating layer 250 on the channel layer 240; and a gate electrode 260 on the gate insulating layer 250. A plurality of gate electrodes 260 may be provided to be spaced apart from each other in a direction parallel to the channel layer 240. Insulators 270 (e.g. interlayer insulators) configured to separate the adjacent gate electrodes 260 may be provided in spaces between the plurality of gate electrodes 260. However, this is an example and the insulators 270 may be omitted.

The variable resistance layer 230 is or includes or corresponds to a layer that exhibits different resistance characteristics depending on an applied voltage, and according to an electric field formed in the variable resistance layer 230, a conductive filament may be formed by the behavior of oxygen occurring in the variable resistance material included in the variable resistance layer 230, resulting in the resistance of the variable resistance layer 230 being changed (e.g. increased and/or decreased). In other words, oxygen vacancies, e.g. under the influence of an electric field, may gather to form a conductive filament, and when the conductive filament is formed, the resistance of the variable resistance layer 230 may be reduced. Depending on whether or not the conductive filament is formed, the variable resistance layer 230 may exhibit a low resistance state or a high resistance state, and thus, information such as bits of ‘1’ or ‘0’ may be recorded.

An applied voltage for changing the variable resistance layer 230 from a high resistance state to a low resistance state may be referred to as a set voltage Vₛₑₜ, and an applied voltage for changing the variable resistance layer 230 from a low resistance state to a high resistance state may be referred to as a reset voltage Vᵣₑₛₑₜ. The variable resistance memory device 200 according to some example embodiments employs a structure including metal nanoparticles NP in a metal oxide so that oxygen vacancies are well formed in the variable resistance layer 230 to realize a low set voltage.

The variable resistance layer 230 includes a first layer 21 including a metal oxide and metal nanoparticles NP, and a second layer 22 formed on the first layer 21 and including an oxide. The metal nanoparticles NP included in the first layer 21 include a first metal capable of combining to oxygen ions of a metal oxide, and oxygen vacancies Vₒ may increase in the first layer 21 by the metal nanoparticles NP. The second layer 22 is in contact with, e.g. in direct contact with the channel layer 240, and an oxide included in the second layer 22 may be an oxide of a material included in the channel layer 240.

The first metal constituting the metal nanoparticles NP included in the first layer 21 may include one or more of Gd, Sc, Y, Ca, Er, Tm, Ho, Lu, Dy, Th, Be, Sm, Yb, Nd, Mg, Ce, La, Sr, Li, Eu, Al, Hf, Zr, Ba, Eu, or Ti.

The metal oxide included in the first layer 21 is a variable resistance material and may be or may include a metal oxide including oxygen vacancy. The second metal included in the metal oxide may be one or more of Rb, Ti, Ba, Zr, Ca, Hf, Sr, Sc, B, Mg, Al, K, Y, La, Si, Be, Nb, Ni, Ta, W, V, La, Gd, Cu, Mo, Cr or Mn. The metal oxide may be a binary or ternary or higher metal oxide.

Hereinafter, a metal material constituting the metal nanoparticles NP will be referred to as a first metal, and a metal material included in the metal oxide will be referred to as a second metal. The first metal and the second metal are not limited to different metal materials, and may be the same metal material.

The first metal may include a material capable of increasing oxygen vacancies in the variable resistance layer 230 by combining with oxygen ions. To this end, the first metal may include a material having high oxygen bonding stability. Oxygen bonding stability may be expressed as oxide formation energy. The oxide formation energy appears as a negative value, and the greater the absolute value, e.g., the lower the oxide formation energy, the more stable the bonding state with oxygen. The more stable the bonding state between the first metal and oxygen, the oxygen vacancies may be well formed. That the oxygen vacancies are well formed may also be expressed in terms of low oxygen vacancy formation energy. The first metal may be a metal material having an oxide formation energy of −880 kJ/mol or lower. However, example embodiments are not limited thereto, and the first metal may be set according to other requirements. For example, the first metal may be or may include a metal material having an oxide formation energy that is lower than an oxide formation energy of Si.

For example, the oxide formation energy of the first metal may be equal to or less than the oxide formation energy of the second metal. The oxide formation energy of the first metal may be less than that of the second metal, and an absolute value of a difference between the oxide formation energy of the first metal and that of the second metal may be set to a predetermined value or greater. The first metal may be set so that the oxygen vacancy formation energy of the variable resistance layer 230 is low and oxygen vacancies are well formed, and an appropriate combination of the first metal in relation to the second metal included in the metal oxide may be selected. The content of the first metal and/or the size of the metal nanoparticles may be set according to a valence of the first metal.

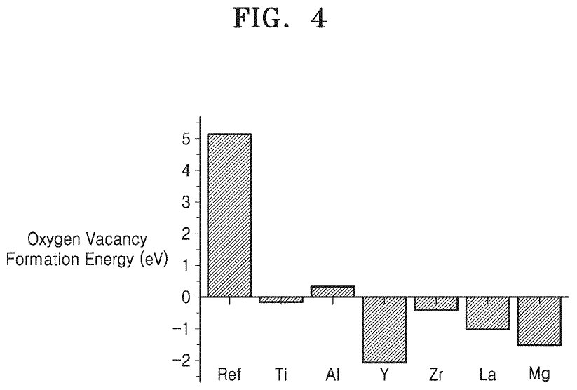

Details of setting the first metal will be described again with reference to FIGS. 4 to 6.

The channel layer 240 may include a semiconductor material. The channel layer 240 may include, for example, doped or undoped single crystal silicon and/or doped or undoped polycrystalline silicon (poly-Si). The second layer 22 in contact with the channel layer 240 may include silicon oxide. The second layer 22 may be a native oxide layer formed by oxidation of portions of the channel layer 240, e.g. by native oxidation of the lower portion of the channel layer 240. The material of the channel layer 240 is not limited to poly-Si, and may include, for example, various semiconductor materials such as one or more of Ge, IGZO, or GaAs. The oxide material included in the second layer 22 may vary according to the material of the channel layer 240.

A source electrode S and a drain electrode D may be connected to respective ends of the channel layer 240.

The gate insulating layer 250 may include various types of insulating materials. For example, one or more of silicon oxide, silicon nitride, or silicon oxynitride may be included in the gate insulating layer 250.

A voltage for turning on/off the channel layer 240 may be selectively/independently applied to each of the plurality of gate electrodes 260.

The variable resistance memory device 200 has a structure in which a plurality of memory cells MC are arrayed (e.g. in an array such as rectangular array), and each of the memory cells MC has a shape in which a transistor and a variable resistor are connected in parallel as shown in an equivalent circuit of FIG. 2. Each variable resistor is set by a voltage applied to the gate electrode 260 and a voltage between the source electrode S and the drain electrode D, and has a value corresponding to information of one bit, e.g., of ‘1’ or ‘0’. Alternatively or additionally, a variable resistor may have a multi-level cell capability, and may be able to store more than one bit; however, example embodiments are not limited thereto.

An operation of the variable resistance memory device 200 will be described with reference to FIG. 3.

When a memory cell to be written to is selected, the gate voltage value of the selected cell is adjusted so that a channel is not formed in the selected cell, for example, the selected cell will become a channel-off cell, and the gate voltage value of the unselected cells is adjusted so that the unselected cells become channel-on cells.

FIG. 3 illustrates a case in which a gate voltage is applied to the gate electrode 260 of each cell so that the central memory cell MC2 is turned off and the two adjacent memory cells MC1 and MC3 are turned on. When a voltage is applied between the source electrode S and the drain electrode D, a conductive path as shown by an arrow A may be formed. By setting an applied voltage as a value of Vₛₑₜ or Vᵣₑₛₑₜ, desired information of ‘1’ or ‘0’ may be written into the selected memory cell MC2.

Similarly, in a read operation, a read with respect to the selected cell may be performed. For example, after a gate voltage applied to each gate electrode 260 is adjusted so that the selected memory cell MC2 is in a ‘channel-off’ state and the unselected memory cells MC1 and MC2 are ‘channel-on’, a cell state (‘1’ or ‘0’) may be determined by measuring a current flowing through the cell MC2 by the applied voltage Vread between the source electrode S and the drain electrode D.

FIG. 4 is a graph illustrating oxygen vacancy formation energies for various materials that may be applied to a variable resistance layer of the variable resistance memory device 200 of FIG. 1.

In the graph, a comparative example is indicated by Ref with the variable resistance layer being SiO₂/HfO₂, and bars appearing next are the first metal constituting the metal nanoparticles NP, for example, the variable resistance layer is SiO₂/(NP+HfO₂). This is the case in which Ti, Al, Y, Zr, La, and Mg of the first metal constitute the metal nanoparticles (NP).

As the oxygen vacancy formation energy Vo has a high positive (+) value, the variable resistance layer is in an unstable state, and forming oxygen vacancies well may be difficult, and/or maintaining the formed oxygen vacancies well may be difficult. Therefore, it is expected that, the higher the oxygen vacancy formation energy, the higher a set voltage Vₛₑₜ for changing the variable resistance layer from a high resistance state to a low resistance state. Conversely, as the oxygen vacancy formation energy has a low negative (−) value, the variable resistance layer is in a stable state, and it is expected that the set voltage Vₛₑₜ is reduced because oxygen vacancies are well formed or the formed oxygen vacancies are maintained well.

As shown in the graph, the case of the variable resistance layer including the metal nanoparticles and the metal oxide shows a lower oxygen vacancy formation energy than the case of the comparative example Ref which uses HfO₂ to which the metal nanoparticles are not added, and thus, it may be seen that nanoparticles may be useful to reduce the set voltage.

The following table shows resistance change layer, oxygen vacancy formation energy of the resistance change layer, and the oxide formation energy of the first metal included as metal nanoparticles in the resistance change layer.

TABLE 1

| | Oxygen vacancy | Oxide formation energy |
|---|---|---|
| variable resistance | formation energy | of first metal |
| layer | (eV) | (kJ/mol) |
| (Comparative example) | 5.16 | |
| SiO₂/HFO₂ | | |
| SiO₂/(Ti—NP) + HfO₂ | −0.07 | −888.8 |
| SiO₂/(Al—NP) + HfO₂ | 0.33 | −1054.87 |
| SiO₂/(Y—NP) + HfO₂ | −2.01 | −1211.07 |
| SiO₂/(Zr—NP) + HfO₂ | −0.31 | −1042.8 |
| SiO₂/(La—NP) + HfO₂ | −0.97 | −1137.2 |
| SiO₂/(Mg—NP) + HfO₂ | −1.43 | −1138.6 |

Reviewing the table, the oxide formation energy of the first metal constituting the metal nanoparticles and the oxygen vacancy formation energy of the variable resistance layer are related to each other. Therefore, the oxygen vacancy formation energy of the variable resistance layer may be reduced by appropriately selecting the first metal in view of the oxide formation energy; accordingly, the set voltage may be reduced.

The following table shows an oxidation formation energy (OFE) for various elements.

TABLE 2

| element | OFE (kJ/mol) |
|---|---|
| Gd | −1213.07 |
| Sc | −1212.93 |
| Y | −1211.07 |
| Ca | −1206.6 |
| Er | −1205.8 |
| Tm | −1196.33 |
| Ho | −1194.07 |
| Lu | −1192.67 |
| Dy | −1181 |
| Th | −1169.2 |
| Be | −1160.2 |
| Sm | −1156.4 |
| Yb | −1151.13 |
| Nd | −1147.2 |
| Mg | −1138.6 |
| Ce | −1137.47 |
| La | −1137.2 |
| Sr | −1123.8 |
| Li | −1122.4 |
| Eu | −1071 |
| Al | −1054.87 |
| Hf | −1053.4 |
| Zr | −1042.8 |
| Ba | −1040.6 |
| Eu | −1037.87 |
| Ti | −888.8 |
| Si | −856.3 |
| V | −808.4 |
| B | −796.2 |
| Ta | −788.28 |
| Na | −751 |
| Mn | −725.8 |
| Nb | −706.4 |
| Cr | −705.4 |
| Ga | −665.5 |
| Zn | −641 |
| W | −533.9 |
| Sn | −503.8 |
| K | −425.1 |
| Pb | −377.8 |
| Ni | −326.3 |
| As | −312.92 |
| Tl | −294.6 |
| Te | −270.3 |
| Pt | −180 |

Elements highlighted in Table 2 are elements applied to metal nanoparticles in Table 1.

When referring to Table 1 and Table 2, the oxygen vacancy formation energy may be reduced by selecting an element having an oxide formation energy of about −880 kJ/mol or lower as the first metal.

All of the oxygen vacancy formation energies shown in Table 1, except for comparative example, are shown to be very low, e.g. positive values close to zero, or negative values. The oxygen vacancy formation energy of the variable resistance layer may be reduced to below a predetermined reference value by appropriately setting the first metal and the second metal. For example, the first metal and second metal may be set so that the oxygen vacancy formation energy of the variable resistive layer is less than 0.5 eV.

Alternatively or additionally, the first metal and the second metal may be selected so that the oxide formation energy of the first metal is equal to or less than the oxide formation energy of the second metal included in the metal oxide.

Alternatively or additionally, the first metal and the second metal may be selected so that the oxide formation energy of the first metal is less than the oxide formation energy of the second metal and an absolute difference thereof is greater than or equal to a predetermined value. For example, the absolute difference of the oxide formation energy may be about 20 kJ/mol or more.

For example, the first metal and the second metal may be selected so that the metal oxide is HfO₂ and the metal nanoparticles are Y, Mg, La, Al, Zr, or Ti. The first metal and the second metal may be selected so that the metal oxide is HfO₂ and the metal nanoparticles are Y, Mg, or La.

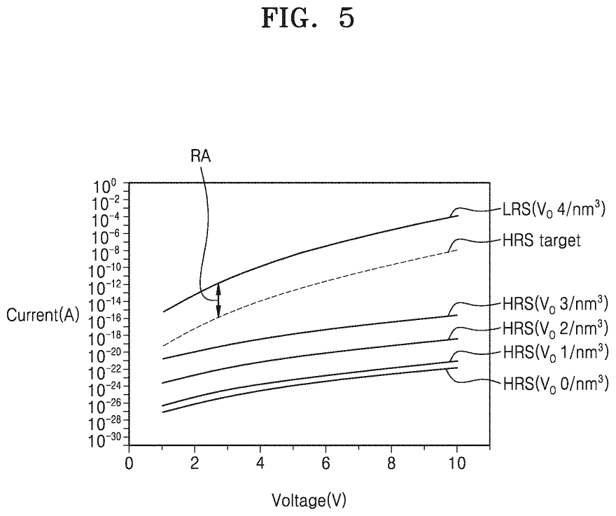

FIG. 5 is a graph conceptually illustrating an I-V curve according to a density of oxygen vacancies that may be formed in a variable resistance layer of the variable resistance memory device of FIG. 1.

In the graph, a current value is calculated considering Poole-Frenkel conduction and Schottky conduction.

First, the current equation by Poole-Frenkel conduction is as follows.

$$J = q μ {N}_{c} E exp ( \frac{- q ( ϕ r - \sqrt{qE / π ε} )}{k T} ) \qquad Equation 1$$

Referring to equation 1, J indicates current density, q indicates unit charge, μ indicates carrier mobility, E indicates the electric field, Nc indicates density state in the conduction band, φ_{T} indicates trap depth, k indicates Boltzmann's constant, T indicates absolute temperature, ε indicates permittivity, and h indicates Planck's constant.

As the number of oxygen vacancies increases, a trap depth decreases. The trap depth means a difference between a trap level and a conduction band minimum in a band diagram. The small trap depth means that electrons at the trap level may move well to the conduction band, and when the electrons move to the conduction band, the electrons may move freely, thus the current density may be increased. Accordingly, the smaller the trap depth, the higher the probability that electrons may ascend to the conduction band. For example, a small trap depth may be advantageous in improving current density.

When the trap depth is large, the current may also flow by Schottky conduction, and it is as follows.

$$J = \frac{4 π {{qm}^{*} ( kT )}^{2}}{{h}^{2}} exp ( \frac{- q ( {ϕ}_{B} - \sqrt{\frac{qE}{Δ π ε}} )}{kT} ) \qquad Equation 2$$

Referring to Equation 2, J indicates current density, Q indicates a unit charge amount, μ indicates a carrier mobility, E is an electric field, k indicates Boltzmann's constant, T indicates an absolute temperature, ε indicates a permittivity, m* indicates an effective mass, h indicates Planck's constant, φ_{B} indicates a conduction band offset (CBO).

The CBO (φ_{B}) and the TRAP depth (φ_{T}) according to the VO number density of the resistance change layer are as follows.

TABLE 3

| | Vo = | Vₒ = | Vₒ = | Vₒ = | Vₒ = |
|---|---|---|---|---|---|
| | 0 | 1/nm³ | 2/nm³ | 3/nm³ | 4/nm³ |
| φ_{B} (eV) | 1.62 | 1.58 | 1.42 | 1.26 | 1.01 |
| φ_{T} (eV) | | 4.31 | 4.31 | 4.07 | 0.56 |

From the graph, the higher the number of oxygen vacancies, the higher the current value at the same voltage.

In the graph, when Vₒ is 4/nm³, this may refer to a low resistance status LRS, and three cases in which Vₒ is 0/nm³, 1/nm³, 2/nm³, and 3/nm³ are indicated as a high resistance state HRS. An HRS Target is depicted as a current level that allows an on/off current ratio to be greater or equal to a predetermined reference value RA. This reference value RA is usually set to about 10⁴. In the case when a current is as high as possible in a range indicating a current level less than the HRS target graph, a set voltage for satisfying a desired on/off current ratio and for a state change to LRS may appear low. From the graph, it is expected that the higher the number of oxygen vacancies, the set voltage may be reduced.

In order to reduce the set voltage, the variable resistance layer may include a first metal and a second metal included in the second layer 22 so that the number of oxygen vacancies per unit volume is 2/nm³ or more, or 3/nm³ or more in a high resistance state.

Alternatively or additionally, the content of the metal nanoparticles included in the variable resistance layer may be set in consideration of a valence of the metal nanoparticles. When the valence of the metal nanoparticles is high, the metal nanoparticles may be more easily combined with oxygen ions, and thus, oxygen vacancies may be more easily formed. When the content of the metal nanoparticles is high, a defect like as the metal nanoparticles are connected in a row may occur, and thus, the size of the metal nanoparticles may be limited to reduce the probability of occurring such defect.

Table 4 below shows the content and size of metal nanoparticles according to a valence of the first metal constituting the metal nanoparticles.

TABLE 4

| | Content of Metal nanoparticle required | | | | |
|---|---|---|---|---|---|
| | for/used for Vₒ formation (at %) | | | | Size of Metal |
| | Vₒ = | Vₒ = | Vₒ = | Vₒ = | Nanoparticle |
| valence | 1/nm³ | 2/nm³ | 3/nm³ | 4/nm³ | (NM) |
| 1 | 14.3 | 25.0 | 33.3 | 40.0 | <1 |
| 2 | 7.7 | 14.3 | 20.0 | 25.0 | <1.5 |
| 3 | 5.3 | 10.3 | 14.3 | 18.2 | <2 |
| 4 | 4.0 | 7.7 | 11.1 | 14.3 | <2.3 |
| 5 | 3.2 | 6.3 | 9.1 | 11.8 | <2.5 |

The size of the metal nanoparticles is presented assuming that the length of the variable resistance layer corresponding to one cell is 10 nm, and the probability that the metal nanoparticles are connected in a row is 0.01% or less. A distance between cells is set according to the degree of integration of the variable resistance memory devices, and 10 nm is an example, and the size of metal nanoparticles based thereon is also an example. One or more of a first metal, a valence, a distance between the cells, and the like may be set, and an appropriate nanoparticle size may be derived.

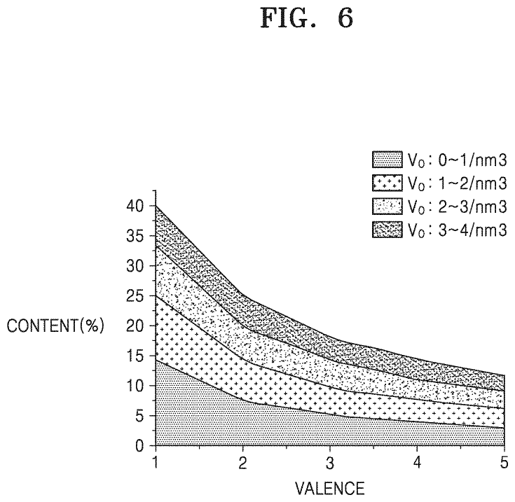

FIG. 6 is a distribution diagram illustrating the number of oxygen vacancies that may be formed in the variable resistance layer according to the valence and/or the content of metal nanoparticles applied to the variable resistance layer of the variable resistance memory device 200 of FIG. 1.

Referring to Tables 3 and 6, the content of the first metal to be applied to the second layer 22 of the variable resistive layer 230 may be set. For example, the content of the first metal may be set to be greater than 0 at % and 40.0 at % or less.

When the valence of the first metal is 1, the amount of the first metal may be in a range from about 25.0 at % to about 33.3 at %. Alternatively, when the valence of the first metal is 2, the content of the first metal may be 25.0 at % or less, or in a range from about 14.3 at % to about 20.0 at %. Alternatively, when the valence of the first metal is 3, the content of the first metal may be 18.2 at % or less, or in a range from about 10.3 at % to about 14.3 at %. Alternatively, when the valence of the first metal is 4, the content of the first metal may be 14.3 at % or less, or in a range from about 7.7 at % to about 11.1 at %. Alternatively, when the valence of the first metal is 5, the content of the first metal may be 11.8 at % or less, or in a range from about 6.3 at % to about 9.1 at %.

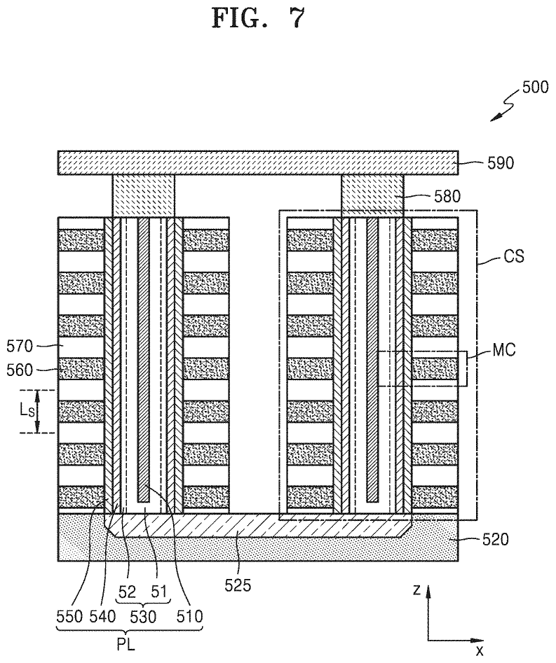

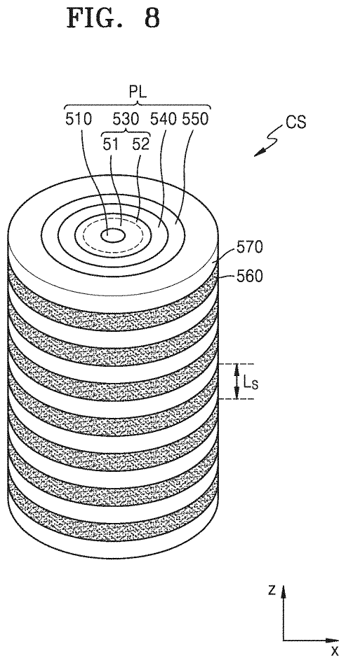

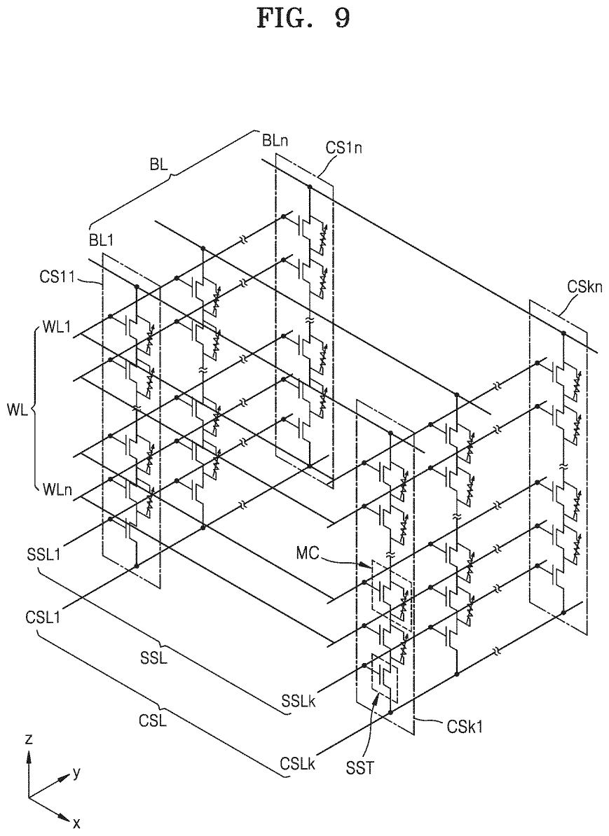

FIG. 7 is a schematic cross-sectional view illustrating a structure of a variable resistance memory device 500 according to various example embodiments, and FIG. 8 is a schematic perspective view illustrating a structure of a memory string included in the variable resistance memory device 500 of FIG. 7. FIG. 9 is an equivalent circuit diagram of the variable resistance memory device 500 of FIG. 7.

The variable resistance memory device 500 according to various example embodiments may be or may include a vertical NAND (VNAND) memory in which a plurality of memory cells MC including a variable resistance material are vertically arrayed.

A detailed configuration of the variable resistance memory device 500 will be described with reference to FIGS. 7 to 9 together.

First, referring to FIG. 7, a plurality of cell strings CS are formed on a substrate 520

The substrate 520 may include a silicon material doped with a first type impurity. For example, the substrate 520 may include a silicon material doped with a p-type impurity such as boron. For example, the substrate 520 may be a p-type well (e.g., a pocket p-well). Hereinafter, the substrate 520 is assumed as p-type silicon. However, the substrate 520 is not limited to p-type silicon.

A doped region 525 that is a source region is provided on the substrate 520. The doped region 525 may be an n-type that is different from that of the substrate 520. Hereinafter, it is assumed that the doped region 525 is n-type such as at least one of phosphorus or arsenic. However, the doped region 525 is not limited to the n-type. The doped region 525 may be connected to a common source line CSL.

As shown in the circuit diagram of FIG. 9, k*n cell strings CS may be provided and arranged in a matrix form, and may be referred to as CSij (1≤i≤k, 1≤j≤n) according to the position of each row and column. Each cell string CSij is connected to a bit line BL, a string select line SSL, a word line WL, and a common source line CSL.

Each cell string CSij includes memory cells MC and a string select transistors SST. The memory cells MC and the string select transistors SST of each cell string CSij may be stacked in a height direction.

Rows of the plurality of cell strings CS are respectively connected to different string selection lines SSL1 to SSLk. For example, the string select transistors SST of the cell strings CS11 to CS1n are commonly connected to the string select line SSL1. The string select transistors SST of the cell strings CSk1 to CSkn are commonly connected to the string select line SSLk.

Columns of the plurality of cell strings CS are respectively connected to different bit lines BL1 to BLn. For example, the memory cells MC of the cell strings CS11 to CSk1 and the string select transistors SST may be commonly connected to the bit line BL1, and the memory cells MC of the cell strings CS1n to CSkn and the string select transistors SST may be commonly connected to the bit line BLn.

Rows of the plurality of cell strings CS may be respectively connected to different common source lines CSL1 to CSLk. For example, the string select transistors SST of the cell strings CS11 to CS1n may be commonly connected to the common source line CSL1, and the string select transistors SST of the cell strings CSk1 to CSkn may be commonly connected to the common source line CSLk.

Gate electrodes of the memory cells MC positioned at the same height from the substrate 520 or the string select transistors SST are commonly connected to one word line WL, and gate electrodes of the memory cells MC positioned at different heights from each other may be respectively connected to different word lines WL1 to WLm.

The circuit structure shown is an example. For example, the number of rows of the cell strings CS may be increased or decreased. As the number of rows of the cell string CS is changed, the number of string selection lines connected to the rows of the cell string CS and the number of cell strings CS connected to one bit line may also be changed. As the number of rows of the cell strings CS is changed, the number of common source lines connected to the rows of the cell strings CS may also be changed.

Alternatively or additionally, the number of columns of the cell strings CS may be increased or decreased. As the number of columns of the cell string CS is changed, the number of bit lines connected to the columns of the cell strings CS and the number of cell strings CS connected to one string selection line may also be changed.

Alternatively or additionally, the height of the cell string CS may also be increased or decreased. For example, the number of memory cells MC stacked on each of the cell strings CS may be increased or decreased. As the number of memory cells MC stacked on each cell string CS is changed, the number of word lines WL may also be changed. For example, the number of string select transistors provided to each of the cell strings CS may be increased. As the number of string select transistors provided to each of the cell strings CS is changed, the number of string select lines or common source lines may also be changed. When the number of string select transistors increases, the string select transistors may be stacked in the same shape as the memory cells MC.

For example, writing and/or reading may be performed in units of rows of the cell strings CS. The cell strings CS may be selected in units of one row by the common source line CSL, and the cell strings CS may be selected in units of one row by the string selection lines SSL. Also, a voltage may be applied to the common source lines CSL as a unit including at least two common source lines. A voltage may be applied to all of the common source lines CSL as a unit.

In the selected row of the cell strings CS, writing and reading may be performed in units of pages. A page may be one row of memory cells MC connected to one word line WL. In the selected row of the cell strings CSs, memory cells MC may be selected in units of pages by word lines WLs.

As shown in FIG. 8, the cell string CS includes a cylindrical pillar PL and a plurality of gate electrodes 560 and a plurality of insulators 570 surrounding the cylindrical pillar PL in a ring shape. The insulator 570 is formed to separate the plurality of gate electrodes 560, and the plurality of gate electrode 560 and the plurality of insulators 570 may be stacked alternately in a vertical direction (Z direction).

The gate electrode 560 may include a metal material and/or a silicon material doped with a high concentration. Each gate electrode 560 is connected to one of a word line WL and a string selection line SSL.

The insulator 570 may include various insulating materials such as silicon oxide and silicon nitride.

The pillar PL may be configured of a plurality of layers. The cylindrical pillar PL includes a supporting layer 510 having a cylindrical shape and extending in a vertical direction and a variable resistance layer 530, a channel layer 540, and a gate insulating layer 550 that are sequentially surrounding the supporting layer 510.

The outermost layer of the pillar PL may be the gate insulating layer 550. For example, the gate insulating layer 550 may include various insulating materials such as one or more of silicon oxide, silicon nitride, or silicon oxynitride. The gate insulating layer 550 may be conformally deposited on the pillar PL.

The channel layer 540 may be conformally deposited/grown along an inner surface of the gate insulating layer 550. The channel layer 540 may include a semiconductor material doped as a first type. The channel layer 540 may include a silicon material doped as the same type as the substrate 520, for example, when the substrate 520 includes a silicon material doped as a p-type, the channel layer 540 may also include a silicon material doped as the p-type. Alternatively, the channel layer 540 may include a material such as Ge, IGZO, GaAs, etc.

The variable resistance layer 530 may be disposed along an inner surface of the channel layer 540. The variable resistance layer 530 may be disposed in contact with the channel layer 540 and may be conformally deposited on the channel layer 540.

The variable resistance layer 530 may be a layer that changes into a high resistance state or a low resistance state according to an applied voltage, and the material and/or characteristics of the variable resistance layer 530 are substantially the same as those of the variable resistance layer 230 described above. The variable resistance layer 530 includes a first layer 51 including metal nanoparticles of a first metal and a metal oxide of a second metal and a second layer 52 including an oxide, such as a native oxide of the channel layer 540. A set voltage for changing from a high resistance state to a low resistance state may be reduced by the metal nanoparticles provided in the variable resistance layer 530.

An insulating material may be deposited along an inner surface of the variable resistance layer 530 to form the supporting layer 510. The supporting layer 510 may have a cylindrical shape filling the innermost space of the pillar PL.

The channel layer 540 and the variable resistance layer 530 may contact the doped region 525, for example, the common source region.

A drain region 580 may be provided on the pillar PL of the cell string CS. The drain region 580 may include a silicon material doped with a second type. For example, the drain region 580 may include a silicon material doped with an n-type.

A bit line 590 may be provided on the drain region 580. The drain region 580 and the bit line 590 may be connected to each other through contact plugs.

A region in which each gate electrode 560, the gate insulating layer 550 at a position facing the gate electrode 560 in a horizontal direction (X direction), the channel layer 540, and the variable resistance layer 530 are disposed constitutes a memory cell MC. For example, the memory cell MC has a circuit structure in which a transistor including the gate electrode 560, the gate insulating layer 550, and the channel layer 540, and a variable resistor formed by the variable resistance layer 530 are connected in parallel.

The structures connected in parallel are continuously arranged in the vertical direction (Z direction) to constitute the cell string CS. In addition, as shown in the circuit diagram of FIG. 9, both ends of the cell string CS may be connected to a common source line CSL and a bit line BL. By applying a voltage to the common source line CSL and the bit line BL, programming, reading, and erasing processes may be performed in the plurality of memory cells MC.

For example, when a memory cell MC to be written to is selected, a gate voltage value of the corresponding cell is adjusted so that a channel is not formed in the selected cell, that is, the channel is turned off, and a gate voltage value of the unselected cells are adjusted so that the unselected cells are channeled on. Accordingly, a current path due to a voltage applied to the common source line CSL and the bit line BL passes through a region of the variable resistance layer 530 of the selected memory cell MC, and at this time, the applied voltage may be set as Vₛₑₜ or Vᵣₑₛₑₜ value and thus, a low-resistance state or a high-resistance state may be made, and desired 1 or 0 information may be written into the selected memory cell MC.

Similarly, in a read operation, a read with respect to the selected cell may be performed. For example, after a gate voltage applied to each gate electrode 560 is adjusted so that the selected memory cell MC is in a channel-off state and unselected memory cells are in a channel-on state, a cell state (1 or 0) may be checked by measuring a current flowing through the corresponding memory cell MC by the applied voltage Vread between the common source line CSL and the bit line BL.

In such a VNAND structure, it is known that there is a limit in increasing the number of gate electrodes 560 included in the cell string CS due to a packaging limit according to a height of the cell string CS. Furthermore, in the case of a charge trap-based memory device, there is a limit in reducing a distance Ls between adjacent cells due to interference. This distance Ls may be expressed as a distance between the centers of two adjacent gate electrodes 560 or the sum of lengths in the vertical direction (Z direction) of the gate electrode 560 and the insulator 570, and thus, a size of one cell is determined. It is known that the distance is difficult to reduce less than about 38 nm in a conventional structure, thus, there is a limit to the memory capacity.

In the variable resistance memory device 500 according to some example embodiments, memory cells MC are configured by applying metal nanoparticles that allow oxygen vacancies to be well formed with a metal oxide in the variable resistance layer 530 and a memory device is implemented by arraying the memory cells MC, and thus, compared to an existing structure, for example, a phase change material-based and/or charge trap-based memory device, the variable resistance layer 530 may be formed to be thin or thinner, and/or to have a lower operating voltage. Alternatively or additionally, it may be advantageous to reduce the distance Ls between adjacent cells, for example, the sum of the lengths in the vertical direction (Z direction) of the gate electrode 560 and the insulator 570. This distance may be less than 20 nm, and may be reduced to about 15 nm. In this case, the memory capacity may be increased greater than twice as compared to a conventional memory device. In this way, the variable resistance memory device 500 may help to solve a scaling issue between memory cells in a next-generation VNAND, thereby increasing density and realizing low power.

The variable resistance memory devices 200 and 500 according to some example embodiments may be employed as a memory system of various electronic devices. The variable resistance memory device 500 may be implemented as a chip-type memory block and may be used as a neuromorphic computing platform or may be used to construct a neural network.

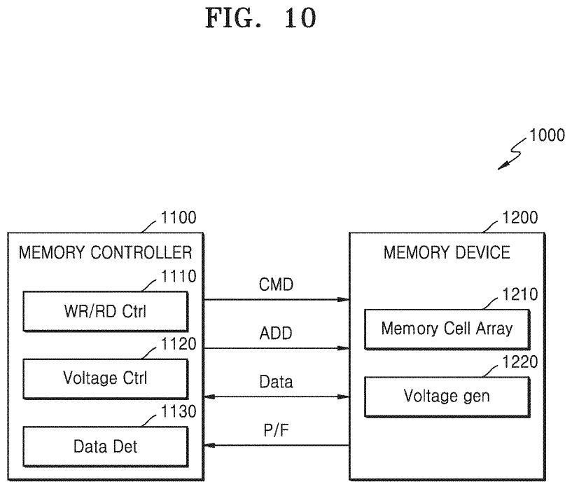

FIG. 10 is a schematic block diagram illustrating a structure of a memory system 1000 according to some example embodiments. Referring to FIG. 10, the memory system 1000 according to some example embodiments may include a memory controller 1100 and a memory device 1200. The memory controller 1100 performs a control operation on the memory device 1200. As an example, the memory controller 1100 may perform program (or write), read, and erase operations with respect to the memory device 1200 by providing an address ADD and a command CMD to the memory device 1200. In addition, data for program operation and read data may be transmitted and received between the memory controller 1100 and the memory device 1200.

The memory device 1200 may include a memory cell array 1210 and a voltage generator 220. The memory cell array 1210 may include a plurality of memory cells disposed in regions where a plurality of word lines and a plurality of bit lines intersect. The memory cell array 1210 may include non-volatile memory cells that store data to be non-volatile, and as non-volatile memory cells, the memory cell array 1210 may include flash memory cells, such as a NAND flash memory cell array 1210, a NOR flash memory cell array 1210, etc. Hereinafter, example embodiments will be described by assuming that the memory cell array 1210 includes the memory cell array 1210 and, accordingly, the memory device 1200 is a non-volatile memory device.

The memory controller 1100 may include a write/read controller 1110, a voltage controller 1120, and a data determiner 1130.

The write/read controller 1110 is configured to generate an address ADD and a command CMD for performing program/read/erase operations on the memory cell array 1210. Also, the voltage controller 1120 is configured to generate a voltage control signal to control at least one voltage level used in the nonvolatile memory device 1200. For example, the voltage controller 1120 is configured to read data from the memory cell array 1210 or generate a voltage control signal for controlling a voltage level of a word line for programming data in the memory cell array 1210.

The data determiner 1130 may be configured to perform a determination operation on data read from the memory device 1200. For example, by determining data read from the memory cells, the data determiner 1130 may determine the number of on memory cells and/or off memory cells among the memory cells. As an example of operation, when programming is performed on a plurality of memory cells, it may be determined whether programming is normally completed for all cells by determining data states of the memory cells by using a predetermined read voltage.

The memory device 1200 may include the memory cell array 1210 and the voltage generator 1220. As described above, the memory cell array 1210 may include non-volatile memory cells, and for example, the memory cell array 1210 may include flash memory cells. In addition, the flash memory cells may be implemented in various forms. For example, the memory cell array 1210 may include three-dimensional (or vertical) NAND (VNAND) memory cells.

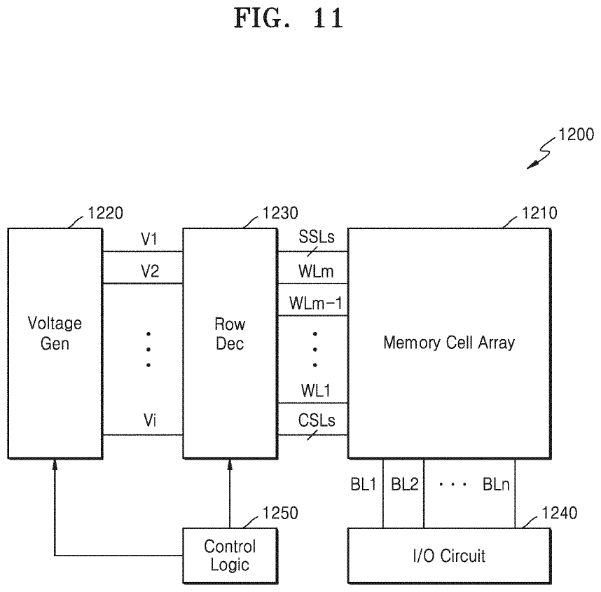

FIG. 11 is a block diagram illustrating an implementation example of the memory device 1200 included in the memory system 1000 of FIG. 10. Referring to FIG. 11, the memory device 1200 may further include a row decoder 1230, an input/output circuit 1240, and a control logic 1250.

The memory cell array 1210 may be connected with or to one or more string selection lines SSL, a plurality of word lines WL1 to WLm, and one or more common source lines CSLs, and also, may be connected to a plurality of bit lines BL1 to BLn. The voltage generator 220 may generate one or more word line voltages V1 to Vi, and the word line voltages V1 to Vi may be provided to the row decoder 1230. Signals for program/read/erase operations may be applied to the memory cell array 1210 through the bit lines BL1 to BLn.

Alternatively or additionally, data to be programmed may be provided to the memory cell array 1210 through the input/output circuit 1240, and read data may be provided to the outside (e.g., a memory controller) through the input/output circuit 1240. The control logic 1250 may provide various control signals related to a memory operation to the row decoder 1230 and the voltage generator 1220.

According to the decoding operation of the row decoder 1230, the word line voltages V1 to Vi may be provided to various lines SSLs, WL1 to WLm, and CSLs. For example, the word line voltages V1 to Vi may include a string selection voltage, a word line voltage, and a ground selection voltage. The string selection voltage may be provided to one or more string selection lines SSLs, the word line voltage may be applied to one or more word lines WL1 to WLm, and the ground selection voltage may be provided to one or more common source lines CSLs.

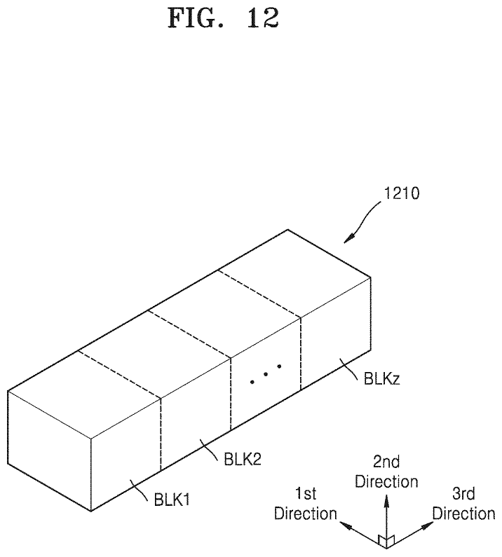

FIG. 12 is a block diagram illustrating the memory cell array 1210 shown in FIG. 10. Referring to FIG. 12, the memory cell array 1210 includes a plurality of memory blocks BLK1 to BLKz. Each of the memory blocks BLK has a three-dimensional structure (or a vertical structure). For example, each memory block BLK may include structures extending in first to third directions. For example, each memory block BLK may include a plurality of memory cell strings extending in the second direction, for example, the cell strings CS illustrated in FIG. 8. The plurality of memory cell strings may be two-dimensionally arranged in the first and third directions. As shown in FIG. 9, each memory cell string is connected to a bit line BL, a string select line SSL, word lines WL, and a common source line CSL. Accordingly, each of the memory blocks BLK1 to BLKz may be connected to a plurality of bit lines BL, a plurality of string selection lines SSLs, a plurality of word lines WL, and a plurality of common source lines CSL. That is, the equivalent circuit shown in FIG. 9 may be an equivalent circuit corresponding to any one of the memory blocks BLK1 to BLKz.

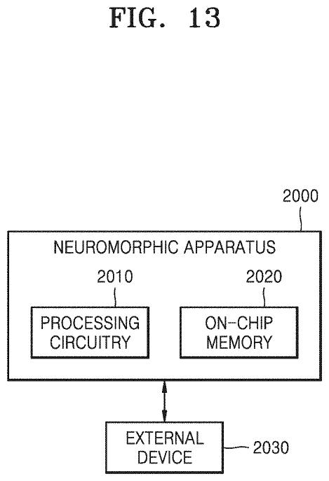

The above-described memory block may be implemented in the form of a chip and may be used as a neuromorphic computing platform. For example, FIG. 13 schematically shows a neuromorphic apparatus 2000 including a memory device according to some example embodiments. Referring to FIG. 13, the neuromorphic apparatus 2000 may include a processing circuit 2010 and/or a memory 2020. The memory 2020 of the neuromorphic apparatus 2000 may include the memory system 1000 according to some example embodiments.

The processing circuit 2010 may be configured to control functions for driving the neuromorphic apparatus 2000. For example, the processing circuit 2010 may control the neuromorphic apparatus 2000 by executing a program stored in the memory 2020 of the neuromorphic apparatus 2000. The processing circuit 2010 may include hardware, such as logic circuitry, a combination of hardware and software, such as a processor that executes software, or a combination thereof. For example, the processor includes one or more of a central processing unit (CPU), a graphics processing unit (GPU), an application processor (AP) in the neuromorphic apparatus 2000, an arithmetic logic unit (ALU), a digital processor, a microcomputer, a field programmable gate array (FPGA), a system-on-chip (SoC), a programmable logic unit, a microprocessor, and an application-specific integrated circuit (ASIC), etc. Alternatively or additionally, the processing circuit 2010 may read and/or write various data from an external device 2030 and execute the neuromorphic apparatus 2000 by using the data. The external device 2030 may include an external memory and/or a sensor array including an image sensor (e.g., a CMOS image sensor circuit).

The neuromorphic apparatus 2000 shown in FIG. 13 may be applied to a machine learning system. A machine learning system may utilize various artificial neural network organizations and processing models including recurrent neural networks (RNNs), stacked neural networks (SNNs), state-space dynamic neural networks (SSDNNs), deep belief networks (DBNs), generative adversarial networks (GANs), and/or restricted Boltzmann machines that optionally include, for example, a convolutional neural network (CNN), a deconvolutional neural network, a long short-term memory (LSTM) and/or a gated recurrent unit (GRU).

The machine learning system may include, for example, linear regression and/or logistic regression, statistical clustering, Bayesian classification, decision trees, dimensionality reduction, such as principal component analysis, and other types of machine learning models, such as expert systems, and/or combinations thereof including an ensemble technique, such as random forests. The machine learning model may be used for providing various services, for example, an image classification service, a user authentication service based on biometric information or biometric data, an advanced driver assistance system (ADAS), a voice assistant service, and an automatic speech recognition (ASR) service, and may be installed and executed in other electronic devices.

In the variable resistance memory device described above, a resistance change from a high resistance state to a low resistance state may occur at a low applied voltage.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

The above-described variable resistance memory device may be easily implemented with low power and high integration, and may be used in various memory systems and electronic devices.

It should be understood that various example embodiments described herein should be considered in a descriptive sense only and not for purposes of limitation. Descriptions of features or aspects within each of various example embodiments should typically be considered as available for other similar features or aspects in other embodiments; and example embodiments are not necessarily mutually exclusive, unless clearly stated and/or clear from context. While one or more embodiments have been described with reference to the figures, it will be understood by those of ordinary skill in the art that various changes in form and details may be made therein without departing from the spirit and scope as defined by the following claims.

What is claimed is:

1. A variable resistance memory device comprising:
a supporting layer including an insulating material;
a variable resistance layer on the supporting layer, and including a first layer including a metal oxide and metal nanoparticles, the variable resistance layer further including a second layer on the first layer and including a second oxide, wherein the metal nanoparticles include a first metal capable of combining with oxygen ions of the metal oxide;
a channel layer on the variable resistance layer;
a gate insulating layer on the channel layer; and
a gate electrode on the gate insulating layer.

2. The variable resistance memory device of claim 1, wherein the second layer contacts the channel layer, and the second oxide included in the second layer includes an oxide of a material of the channel layer.

3. The variable resistance memory device of claim 2, wherein the channel layer includes a polysilicon material, and the second layer includes a silicon oxide.

4. The variable resistance memory device of claim 1, wherein an oxide formation energy of the first metal is lower than the oxide formation energy of Si.

5. The variable resistance memory device of claim 1, wherein an oxide formation energy of the first metal is less than or equal to −880 kJ/mol.

6. The variable resistance memory device of claim 1, wherein an oxide formation energy of the first metal is less than or equal to an oxide formation energy of a second metal included in the metal oxide.

7. The variable resistance memory device of claim 1, wherein a second metal included in the metal oxide is one of Rb, Ti, Ba, Zr, Ca, Hf, Sr, Sc, B, Mg, Al, K, Y, La, Si, Be, Nb, Ni, Ta, W, V, La, Gd, Cu, Mo, Cr, or Mn.

8. The variable resistance memory device of claim 1, wherein the first metal included in the metal nanoparticles is one of Gd, Sc, Y, Ca, Er, Tm, Ho, Lu, Dy, Th, Be, Sm, Yb, Nd, Mg, Ce, La, Sr, Li, Eu, Al, Hf, Zr, Ba, Eu, or Ti.

9. The variable resistance memory device of claim 1, wherein the metal oxide is HfO₂, and the metal nanoparticles are one or more particles of Y, Mg, La, Al, Zr, or Ti.

10. The variable resistance memory device of claim 9, wherein the metal oxide is HfO₂, and the metal nanoparticles are one or more particles of Y, Mg, or La.

11. The variable resistance memory device of claim 1, wherein an oxide formation energy of the first metal is less than an oxide formation energy of a second metal included in the metal oxide, and an absolute value difference between the oxide formation energy of the first metal and the oxide formation energy of the second metal is 20 kJ/mol or more.

12. The variable resistance memory device of claim 1, wherein an oxygen vacancy formation energy of the variable resistance layer is lower than 0.5 eV.

13. The variable resistance memory device of claim 1, wherein when the variable resistance layer being is a high resistance state, a number of oxygen vacancies per unit volume is 2/nm³ or more.

14. The variable resistance memory device of claim 1, wherein a diameter of the metal nanoparticles is less than 2.5 nm.

15. The variable resistance memory device of claim 1, wherein a content of the first metal included in the second layer is greater than 0 at % and less than or equal to 40.0 at %.

16. The variable resistance memory device of claim 1, wherein a valence of the first metal is 1, and a content of the first metal is in a range from about 25.0 at % to about 33.3 at %.

17. The variable resistance memory device of claim 1, wherein a valence of the first metal is 2, and a content of the first metal is in a range from about 14.3 at % to about 20.0 at %.

18. The variable resistance memory device of claim 1, wherein a valence of the first metal is 3, and a content of the first metal is in a range from about 10.3 at % to about 14.3 at %.

19. The variable resistance memory device of claim 1, wherein a valence of the first metal is 4, and a content of the first metal is in a range from about 7.7 at % to about 11.1 at %.

20. The variable resistance memory device of claim 1, wherein a valence of the first metal is 5, and a content of the first metal is in a range from about 6.3 at % to about 9.1 at %.

21. The variable resistance memory device of claim 1, wherein the gate electrode includes a plurality of gate electrodes spaced apart from each other in a first direction parallel to the channel layer, and a plurality of insulators are respectively between the plurality of gate electrodes.

22. The variable resistance memory device of claim 21, wherein the supporting layer has a cylinder shape extending in the first direction, and the variable resistance layer, the channel layer, the gate insulating layer, and the plurality of gate electrodes have a shape surrounding the insulating layer.

23. The variable resistance memory device of claim 21, wherein a length in the first direction between a centers of two adjacent gate electrodes among the plurality of gate electrodes is less than 20 nm.

24. The variable resistance memory device of claim 21, further comprising:
a drain region in contact with one end of the channel layer and a source region in contact with another end of the channel layer and with the variable resistance layer, the one end and the other end in the first direction.

25. The variable resistance memory device of claim 24, further comprising:
a bit line connected to the drain region, a source line connected to the source region, and a plurality of word lines respectively connected to the plurality of gate electrodes.

26. A memory system comprising:
a memory device including a memory cell array in which a plurality of memory cells including the variable resistance memory device of claim 1 are arrayed; and
a voltage generator configured to generate a voltage to be applied to the memory cell array, and a memory controller configured to control the memory device.
